(19) United States
(12) Patent Application Publication
(10) Pub. No.: US 2007/0152854 A1
(43) Pub. Date: Jul. 5, 2007

(54) FORGERY DETECTION USING ENTROPY MODELING

(76) Inventor: Drew Copley, Aliso Viejo, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/613,932

(22) Filed: Dec. 20, 2006

Related U.S. Application Data
(60) Provisional application No. 60/754,841, filed on Dec. 29, 2005.

(51) Int. Cl. H03M 7/38

(52) U.S. Cl. 341/51

(57) ABSTRACT

In accordance with one or more embodiments of the present invention, a method of determining a suspect computer file is malicious includes parsing a suspect file to extract a byte code sequence, modeling the extracted byte code sequence using at least one entropy modeling test where each modeling test provides an entropy result based on the modeling of the extracted byte code sequence, comparing each entropy result to a table of entropy results to determine a probability value, and summing the probability values to determine a likelihood the byte code sequence is malicious.

### CROSS-REFERENCE TO RELATED APPLICATION

This application relies for priority upon a Provisional Patent Application No. 60/754,841 filed in the United States Patent and Trademark Office, on Dec. 29, 2005, the entire content of which is incorporated by reference.

### TECHNICAL FIELD

The present invention relates generally to computer security, and particularly to forgery detection.

### BACKGROUND

In general, traditional AV (anti-virus or anti-viral) computer security systems may operate using a “black list”. That is, the system may access a list of characteristics associated with known malicious files, denoted as malware, and then use this list of characteristics for comparison with suspect files coming under examination. These characteristics are generally blind in nature, and usually consist of some form of exact or nearly exact byte code combinations.

Alternatively, “white list” systems typically are not considered anti-viral systems even though they usually boast many of the advantages associated with an anti-viral system. White list systems traditionally operate in a very strict manner, unlike black list systems, since a white list system typically keeps a byte code list based on signature hashing or cryptographic technology and may apply this list to any new file or attempted file changes. In this manner, any legitimate file put onto the computer system must first be validated by a central controller, which will ultimately require manual intervention, as opposed to a more automated process. Historically, there has been very little work done to make a more heuristic type of white list computer security system.

A problem with these kinds of systems is that the more dynamic the system is, the more false positives, or falsely labeled malicious files, tend to be detected. Processing demands also tend to increase quite significantly as the number of “good” file attributes and “bad” file attributes tend to increase within encountered files. Therefore, there remains a need in the art for methods and systems to provide a more effective and efficient way to detect unwanted or malicious code while improving security system performance.

### SUMMARY

A white list heuristic analysis system is designed to detect “forged” computer system files in order to identify these files as malicious. While “white list” systems may be generally designed to reduce the number of exact match signatures that “black list” systems may demand, a “white list” system may be more adaptable to quantify what files are allowed versus files that are not allowed since the focus may be on quantifying and classifying allowed so-called “knowns” instead of the impossible task of describing so-called “unknowns”. More particularly, the present disclosure includes a method for analysis of byte code sequences using entropy modeling for the purposes of heuristic information analysis, where one of a probabilistic and a deterministic value is used to determine the likelihood that the byte code sequence is malicious.

In accordance with one embodiment of the present invention, a method of determining a suspect computer file is malicious includes parsing a suspect file to extract a byte code sequence, modeling the extracted byte code sequence using at least one entropy modeling test where each modeling test provides an entropy result based on the modeling of the extracted byte code sequence, comparing each entropy result to a table of entropy results to determine a probability value, and summing the probability values to determine a likelihood the byte code sequence is malicious.

In accordance with another embodiment of the present invention, a computer readable medium on which is stored a computer program for executing instructions including parsing a suspect file to extract a byte code sequence, modeling the extracted byte code sequence using at least one entropy modeling test where each modeling test provides an entropy result based on the modeling of the extracted byte code sequence, comparing each entropy result to a table of entropy results to determine a probability value, and summing the probability values to determine a likelihood the byte code sequence is malicious.

In accordance with another embodiment of the present invention, a malware resistant computer system includes a processing unit, a memory unit, and a computer file system, wherein the processing unit is configured to execute operations to detect malware, the operations including parsing a suspect file to extract a byte code sequence, modeling the extracted byte code sequence using at least one entropy modeling test where each modeling test provides an entropy result based on the modeling of the extracted byte code sequence, comparing each entropy result to a table of entropy results to produce a probability value, and summing the probability values to determine a likelihood the byte code sequence is malicious.

In accordance with another embodiment of the present invention, a method of detecting malware includes the operations of receiving a suspect file, preparing the received suspect file, performing a heuristic analysis on the prepared suspect file using a plurality of entropy modeling tests to provide a plurality of entropy results, performing a rule processing analysis on the plurality of entropy results to provide a plurality of deterministic results, and declaring the suspect file is malware when a weighted sum of the deterministic results exceeds a predetermined threshold value.

The scope of the present invention is defined by the claims, which are incorporated into this section by reference. A more complete understanding of embodiments of the present invention will be afforded to those skilled in the art, as well as a realization of additional advantages thereof, by a consideration of the following detailed description. Reference will be made to the appended sheets of drawings that will first be described briefly.

### BRIEF DESCRIPTION OF THE DRAWINGS

FIG. 1 shows a flow diagram illustrating an exemplary embodiment of an entropic analysis flow, in accordance with an embodiment of the present invention.

FIG. 2 shows an exemplary computer system for implementing forgery detection using entropy modeling, in accordance with an embodiment of the present invention.

Embodiments of the present invention and their advantages are best understood by referring to the detailed description that follows. It should be appreciated that like reference numerals are used to identify like elements illustrated in one or more of the figures.

### DETAILED DESCRIPTION

A white list heuristic analysis system detects “forged” computer system files in order to identify these files as malicious. One or more embodiments of the present invention include analysis of byte code sequences using entropy modeling for the purposes of heuristic information analysis. A file under inspection may be parsed to extract one or more entropy results from one or more sets of entropic analysis tests for comparison against past-known good and bad entropic test results. In this manner, the probability the file is a forgery, and considered malicious, may be deduced. Specifically, a file that purports to be “safe to run”, or a “good” file, yet lacks the characteristics of a safe or good file, should be regarded as malicious. Further, instead of a probabilistic comparison, exact or near exact matches may be considered against the entropic analysis result with the results of the comparison being weighted. The weights and/or probabilities may be determined when the lists are created.

Modeling a byte code sequence taken from a sample file through entropy analysis may provide a fuzzy, or generalized, representation of that code sequence which is pseudo-static across changes to that code sequence. Further, creating a table for these entropy values of good code sequences and bad code sequences may provide a basis for using a Bayesian, or conditional probability model of the data that is useful in comparing new code sequences from files under inspection as well as to ascertain whether the new code sequence is likely to be malicious or benign, that is either harmful or harmless. Once the file or byte code sequence is determined to be malicious, the file containing the malicious code may be disposed of or handled in an appropriate manner, including quarantine, deletion, and/or moving to a safe repository for later review. Depending on particular conditions, a single entropic measurement may not be specific enough for a byte code sequence, so modeling the data using n-gram/x-order Markov models may provide additional entropic measurements and more specificity. In combination, a plurality of singular entropic results may provide a valuable, fuzzy representation of the byte code sequence. The results of each singular entropic test may be compared with the results of other entropic tests.

As used herein, the term malware or the phrase malicious software can refer to any undesirable or potentially harmful computer file, data, or program code segment. Similarly, the term spyware can include any type of spying agent or information gathering code sequence, even including trojans and rootkits, not just traditional spyware. Protection against spyware may be the first priority for modern anti-malware systems. The term “forgery” herein refers generally to the maliciousness of files in the context of a computer system. Good files may be designed to be benign or benevolent (i.e. in some way positively functional), whereas malicious files are typically designed to be deliberately harmful and therefore considered to be “forgeries”. That is, in the “white list” model of security, any file which poses as legitimate by the very fact of being a file created by a person or by another application a person created or modified to effectively create essentially is a “forgery” in that it is not a legitimate application or file but it is an illegitimate file with malicious intent. In particular, a forgery is intended to include all malicious files including so-called “system” malicious files.

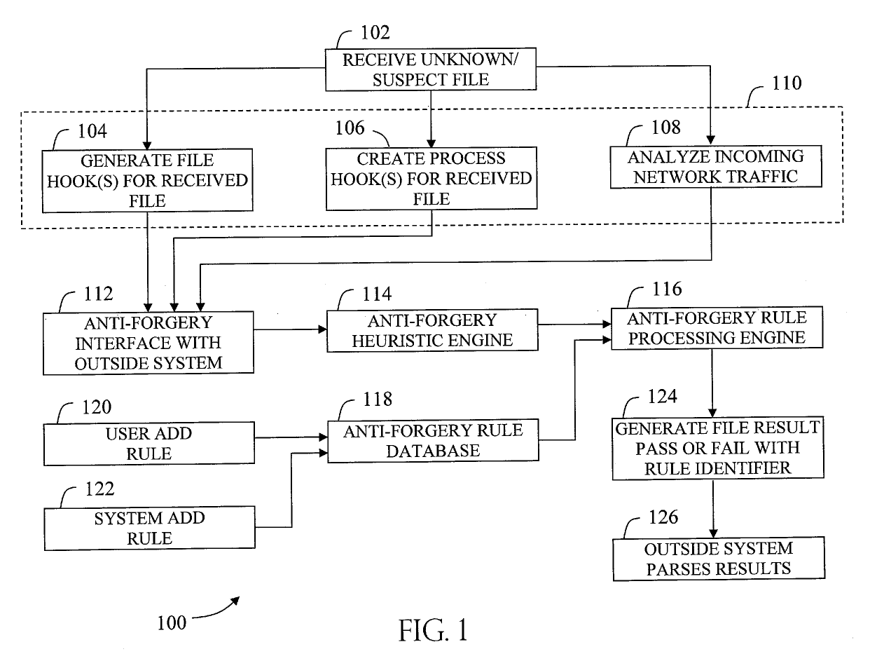

FIG. 1 shows a flow diagram illustrating an exemplary embodiment of an entropic analysis flow 100, in accordance with an embodiment of the present invention. Flow 100 can include operations to provide parsing the suspect file to extract a byte code sequence, modeling the extracted byte code sequence using a plurality of entropy modeling tests where each modeling test produces an entropy result, comparing each entropy result to a table of entropy results to produce a probability value, and/or summing the plurality of probability values to determine a likelihood the byte code sequence is malicious. The byte code sequence may be deemed malicious when the sum of the plurality of probability values exceeds a predetermined threshold value. The sum may be deemed to exceed a threshold value when the sum is below a lower bound or above an upper bound.

In reference to FIG. 1, flow 100 may include one or more of the following operations. Flow 100 may include receiving an unknown or suspect file in operation 102, where receiving can include storing a file in a memory device such as a Random Access Memory (RAM), a disc drive, a buffer, and/or any temporary or permanent storage device. Once the unknown or suspect file is received, flow 100 may continue with generating one or more file hooks for the received file in operation 104, creating one or more process hooks for the suspect file in operation 106, and/or analyzing incoming network traffic related to the suspect file in operation 108, which may be considered as preparing the suspect file for analysis in operation 110.

Flow 100 may continue with providing the generated file hooks, process hooks, and/or an analysis of incoming network traffic to an anti-forgery interface with an outside system in operation 112. Flow 100 may continue with examining the output of the outside system with an anti-forgery heuristic engine in operation 114. The anti-forgery heuristic engine may provide an Entropic Analysis result that is examined by an anti-forgery rule processing engine in operation 116, whereby the entropic analysis result is applied against, or compared with, a list of positive (good) and bad (malicious) previously known entropic results, and the sums of the probability of the validity of the file may be finally judged in view of, or against, these probabilities. In general terms, operation 112 may provide an interface between one or more external systems or processes that may acquire a file for inspection as well as the heuristic analysis engine itself. Operation 112, therefore, may include a system for converting an acquired file to a parse-able format for subsequent operations. In this manner, operation 114 may include parsing a raw file, decompressing the file for proper analysis, and/or may include a messaging system to reply to a sending system in acknowledgement that a file has been taken for parsing.

The anti-forgery rule processing engine may receive a plurality of rules from an anti-forgery rule database in operation 118, where rules may be provided by user added rules determined manually in operation 120, and/or system added rules determined automatically in operation 122. In the case of either the automatically added or user added rules, where a user here may include any user, system, or individual that supplies rules for others of the same, such as a vendor or network administrator, the rules may be added to a list in a “white list” and/or “black list” fashion. After this, the overall system may analyze the found, or determined, entropic results against these rules in at least one of a probabilistic or a deterministic fashion. That is, the rules may be applied according to other rules automatically in a non-weighted manner, or the rules may be applied in a weighted manner where exact matches to criteria are used. In the exact match or probabilistic analysis system, logical operators may be applied to aid in determining the final analysis. Flow 100 may continue with the rule processing engine in operation 116 providing an output that is used to generate a file result, comprising a pass or fail determination on whether the suspect file is malware, in operation 124. Flow 100 may conclude with the pass/fail result being provided to the outside system in operation 126, or the result may be stored and/or accumulated with other results for later use.

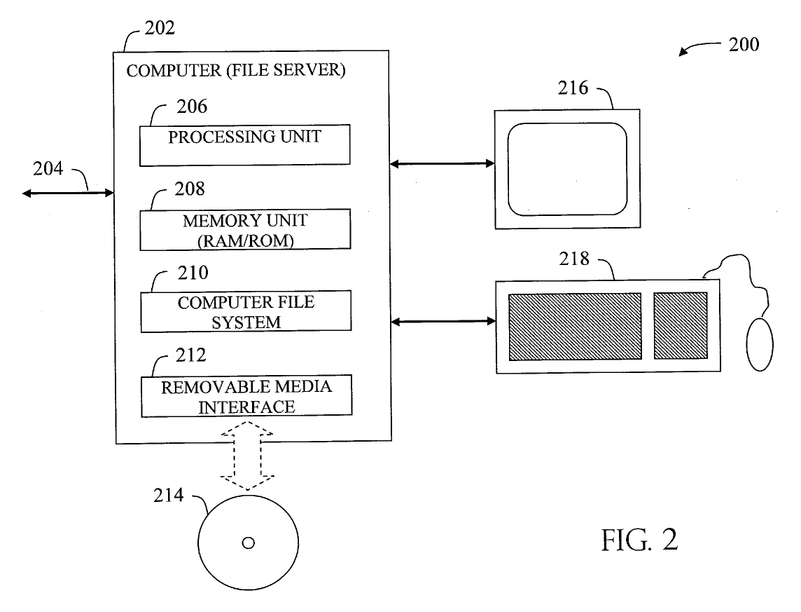

FIG. 2 shows an exemplary computer system 200 configured for implementing forgery detection using entropy modeling flows, including flow 100. Computer system 200 may include a computer or file server 202 connected to an interconnection network 204 and configured to exchange messages with another computer or server connected to network 204. Computer 202 may include a network interface and/or connection for sending and receiving information over a communications network 204. Computer 202 may include a processing unit 206, comprising a suitably programmed computer processor, configured to fetch, decode, and execute computer instructions to move data and perform computations, a memory unit 208 for storing computer instructions and data, and a computer file system 210 for storing and retrieving computer files. Memory unit 208 can include a Random Access Memory (RAM) and a Read Only Memory (ROM) as example media for storing and retrieving computer data including computer programs for use in processing by processing unit 206. Similarly, computer file system 210 can include an optical or magnetic disc as exemplary media for reading and writing (storing and retrieving) computer data and program instructions. Computer 202 may include a removable media interface 212 configured to operate with a removable media element 214 such as a removable computer readable medium including a computer disc (optical or magnetic) or a solid-state memory. A typical computer 202 interfaces with a monitor 216, a keyboard/mouse 218, where a user-console is desirable.

Computer system 202 may receive a malicious computer file from network 204 or removable media 214, and any of the above media may be used to store and retrieve data that may contain malicious computer files. Network 204 may connect to a Local Area Network (LAN), a Wide Area Network (WAN), and/or the Internet so that a suspect file may be accessed in another computer or file system having a memory unit, computer file system, and/or removable memory element, for example. In this manner, a local computer system 200 may perform rigorous forgery detection on files located on a remote system.

A primary advantage of fuzzy modeling of byte code signatures is that a certain level of change may be made across malicious or non-malicious binary files, but the entropic signature may remain static. This may allow for positive identification of the byte code sequence even if it has been partially changed, including re-used or recycled code that is altered to avoid detection while preserving functionality. Further, entropy modeling may provide identification in a manner that is both extremely fast and accurate. In particular, X-order modeling of the data for entropic analysis may be generally useful, but additional modeling techniques may also be used including skipping X-sequence of bytes and then modeling the data using X-order Markov models (including 0-order), a 0-order arithmetic analysis, a 1-order uni-gram test, and a 2-order bi-gram test. In this disclosure, the phrases X-order test, X-order model, and X-order analysis should be considered equivalent. Shannon's equation for estimation of entropy for a set of data has been found to be useful, as well as other techniques to provide an estimation of entropy, such as arithmetic sums and the Chi-Square distribution test. The result of this type of modeling may include a sequence of numbers that may then represent the static sequence of bytes in a fuzzy manner. For example:

(8BFF558BEC538B5D08568B750C85F6578B7D107509833DCC,487925,14855,550163,558496)

(8BFF558BEC538B5D08568B750C85F6578B7D107509833D20,487925,14855,550163,558496)

(8BFF558BEC538B5D08568B750C85F6578B7D107509833DC8,487925,14855,550163,558496)

(8BFF558BEC538B5D08568B750C85F6578B7D107509833DF4,487925,14855,550163,558496)

(8BFF558BEC538B5D08568B750C85F6578B7D107509833DF4,487925,14855,550163,558496)

(8BFF558BEC538B5D08568B750C85F6578B7D107509833D7C,487925,14855,550163,558496)

(8BFF558BEC538B5D08568B750C85F6578B7D107509833DB4,487925,14855,550163,558496)

(8BFF558BEC538B5D08568B750C85F6578B7D100F84E10100,487925,14855,550163,558496)

Each one of the above rows may represent a sequence of bytes taken from a different binary file at a fixed location. The first column is the string of bytes. The next columns are the results from various entropy tests on the value in the first column. Exact code byte signatures may be performed on this analysis for maximum specificity. In the above example, the first bytes, “8BFF558BEC538B” are at the beginning of the string. Alternatively, the first bytes and x-other bytes in whatever order may also be in the string. In this case, column 1 above shows an exact byte code match string. Columns 2-5 result from various entropic analysis tests on the value in column 1. In this manner, each row represents the exact match data (shown in column 1) and the corresponding entropic analysis results (columns 2-5), where each row is a different sample. In this example, each sample is taken from the same relative place or location in different files.

In the above description, while the strings may be somewhat different they may have the exact same entropic representation. In general terms, entropy tests analyze data in terms of probability in order to deduce an entropic or distribution range, that may be termed a range of entropic dispersion. To illustrate, a simple entropic analysis of a 21-byte random string, such as “YIUYIOUYOIUTTFKJHFVBD”, may include taking each single byte and comparing it to every other byte in the string. This can include the determination that, “Y” (first byte) occurs three times within a string having a length of 21 bytes, “I” (second byte) also occurs three times within the 21 byte string, and so on for each element. Similarly, portions of the string may be grouped into a set having a length of two or more elements. In this case, two bytes may be taken at a time and compared with the string, or three bytes may be taken at a time and compared with the string, and so on. In an “arithmetic” analysis method, bytes in the string may be compared with their immediate neighbors. Other analysis methods are possible, including a natural language formulation where comparisons are made on a “per word” basis. In these and other examples, the set size may be significant, since the set size determines the number of comparisons required, among other artifacts. For raw data, a preferred group size is 255 bytes, while in a programming language analysis, the programming instructions may be compared with the frequency of other programming instructions encountered elsewhere. A common theme is that the probabilistic analysis, using any mix of the above methods and others, provides a range of entropic dispersion.

The following example includes two different code byte sequences taken from two different files with different entropy values:

(6A7068703D0001E85C02000033DB895DFC8D458050FF15DC,468321,42171,527757,558496)

(8BFF558BEC538B5D08568B750C85F6578B7D107509833D64,478019,14855,545996,554330)

Relying entirely on code byte signatures mixed with entropic returns, however may not be as effective as modeling the data based on the probability of returns against bad set X of entropic data and good set Y of entropic data—that is, by applying the Bayesian Theorem to the entropic figures in order to determine or deduce the likelihood that a piece of data belongs in good set Y or bad set X.

In another example, the following values:

(558BEC538B5D08568B750C85F6578B7D100F84A8DD020083,482945,0,544424,554330)

(558BEC538B5D08568B750C85F6578B7D107509833D1C21B8,487112,0,550163,558496)

Within a narrow range of values, these entropic returns tend to be within a set, static array of difference. For instance, in the above two strings the entropic values are generally different between each other, yet the second entropic value is equal. Across larger ranges of sets of similar data, experimental results show there is a range of values returned for similar strings. For instance:

(558BEC538B5D08568B750C85F6578B7D107509833D245285,480351,0,545996,554330)

(558BEC538B5D08568B750C85F6578B7D107509833D306267,488684,0,550163,558496)

(558BEC538B5D08568B750C85F6578B7D107509833DDC6E61,492851,0,550163,558496)

(558BEC538B5D08568B750C85F6578B7D107509833DC00758,482945,0,550163,558496)

(558BEC538B5D08568B750C85F6578B7D107509833D6C8850,492851,0,550163,558496)

(558BEC538B5D08568B750C85F6578B7D107509833D20BC98,487112,0,550163,558496)

(558BEC538B5D08568B750C85F6578B7D107509833D181742,487112,14855,550163,558496)

In the above values a number of repeating entropic returns values remain across columns, even while the entire return of entropic data returned may not be the same. In this example, the second to last column shows the figure “550163” multiple times, while the first entropic column shows “487112” multiple times, and the second entropic column shows “0” multiple times. Across larger sets of data little variance has been found between changes of the byte code sequence and the entropic returns. Experimentally, some variance has been found, but this variance has been within a small range of data. The above examples were taken from similar code of a non-malicious nature. Similarities may be found in the data as well as in the entropic returns. For example, two different figures above return two sets of data:

(558BEC538B5D08568B750C85F6578B7D107509833D245285,480351,0,545996,554330)

(8BFF558BEC538B5D08568B750C85F6578B7D107509833D64,478019,14855,545996,554330)

While both of the two above strings may appear to be different, they have similar entropic returns in the last two columns. However, upon closer examination of the strings show they both contain this sequence of bytes:

“558BEC538B5D08568B750C85F6578B7D107509833”

Yet, while examining malicious returns of an entirely different nature, the variance in the entropy returns may be quite different:

(6854124000E8EEFFFFFF0000000000003000000038000000,348093,97034,420996,468872)

(00008B7D106683FF01740A6683FF020F85D2020000A10060,413738,35336,505351,533496)

(9068BDAB0901589090BF1C4046009090BE9805000031043E,349409,67468,420996,447448)

Three primary ways to model these entropic returns provide fuzzy analysis of new strings. These ways to model are:

1. Use static code byte signatures in combination with fuzzy entropic modeling;

2. Create decision trees populated with likely entropy returns in order for comparison.

As an alternative, a third way to model may include

3. Inputting the occurrences of entropic returns into a Bayesian model of X bad data set and Y good data set and comparing the data obtained in this way based on the probability of each entropic return being either good or bad, and then summing the difference between the two probability returns.

There are primary problems with the first two methods if used without additional Bayesian support. The first method tends to require exhaustive searching of the string, which consequently lowers performance. The second method may be problematic if the set of data for comparison is not large enough, since a string might be improperly recognized by the entropic analysis figures alone. The third method, however, allows for additional types of string variants to be found with new entropy measures and it allows for accurate rendering of good data versus bad data without exhaustive string searches. The first and second methods may come into play with the third method. The primary reason is that it may be necessary to first bookmark a position within a file in order to extract the signature bytes of data, to ensure certain bytes do exist within this signature, or that certain entropy values do exist. Methods and systems disclosed in accordance with one or more embodiments of the present invention may include any variation of the above methods.

In one example, among various application examples, a bookmark check at the Entry Point of a Win32 Portable Executable (PE) file where a sample includes X number of bytes. All of the above figures were taken from binary entry points. By profiling the entropic data against a predetermined number X of bad data sets and predetermined number Y of good data sets the probability of a file being malicious or non-malicious may be determined. For each of the X and Y data sets, it is preferred that the profile include at least ten entropy results for comparison, where the X data set may be gleaned by performing an entropy analysis on a known bad file that contains malware and the Y data set may be gleaned by performing an entropy analysis on a known good file that does not contain malware. This probability can then be used with additional tests of this method or other methods in order to further ascertain the overall likelihood whether the file under examination is malicious or benign.

The PE file format is generally the format of w32, Windows® 32-bit executables, where each w32 file includes various sections. For example, a w32 file may include an import section where one or more Application Programming Interfaces (APIs) may be placed, an export section where APIs exported by the file may be placed, a preliminary shell data section, and the Entry Point (EP) of the code. A definition section may describe divisions within the file. Other applications within a binary file may model a code byte signature around a function call (e.g. for SMTP functionality) and compare this code to previous malicious functionalities of this code against benign usages of this code and derive a probability of the usage of this functionality whether it is likely to be good or bad.

Packing and/or encrypting files may include creating a new shell for the original binary executable, moving the original binary to a new location, and covering the original binary with the new shell. The contents or the data of the original file may be encrypted, packed, or both encrypted and packed. Once the file is packed/encrypted, the packer/encryptor is executed instead of the original binary, which then unpacks/decrypts the contents of the original file in memory, then the original file may be loaded and executed. One type of attack against packed/encrypted malware may include finding when and where the original file is made complete in memory, then dumping the completed file process from memory to a file. To do this, the Original Entry Point (OEP) is determined.

An state type heuristic check that a heuristic engine may do includes determining whether the suspect file or any portion thereof is packed and/or encrypted. This can include investigating whether a first section of the file is packed or encrypted, examining the section names and comparing with expected values, and/or investigating the existence of a packer/encryptor code signature. Entropy checks may include manual inspection, generally accepted ‘good usage’, and “zero order” entropy in a PE file identifying tool (PEiD).

Although the invention has been described with respect to particular embodiments, this description is only an example of the invention's application and should not be taken as a limitation. It should also be understood that numerous modifications and variations are possible in accordance with the principles of the present invention. Accordingly, the scope of the invention is defined only by the following claims.

I claim:

1. A method of determining a suspect computer file is malicious, comprising the operations of:
parsing a suspect file to extract a byte code sequence;
modeling the extracted byte code sequence using at least one entropy modeling test, each modeling test providing an entropy result based on the modeling of the extracted byte code sequence;
comparing each entropy result to a table of entropy results to determine a probability value; and
summing the probability values to determine a likelihood the byte code sequence is malicious.

2. The method of claim 1, wherein the byte code sequence is deemed malicious when the sum of the probability values exceeds a predetermined threshold value.

3. The method of claim 1, further comprising disposing of the suspect file when the byte code sequence is determined to be malicious.

4. The method of claim 3, wherein disposing of the malicious file includes at least one of quarantining the malicious file and deleting the malicious file.

5. The method of claim 1, wherein the entropy modeling test is selected from a group consisting of a 0-order Markov test, a 0-order arithmetic test, a 1-order uni-gram test, and a 2-order bi-gram test.

6. The method of claim 1, wherein the entropy modeling test includes a singular test configured to return the entropy of a string in the suspect file.

7. The method of claim 1, wherein the entropy modeling test is selected from a plurality of different entropic modeling tests, wherein the result of each test is analyzed one of singularly and in relation to the other of the plurality of entropic tests.

8. The method of claim 1, wherein the process of comparing each entropy result further comprises profiling the entropy results against at least one of a first predetermined number of bad data sets and second predetermined number of good data sets to produces the probability result.

9. The method of claim 1, wherein the process of modeling the extracted byte code sequence includes at least one of:
combining at least one static code byte signature with the entropy modeling;
creating at least one decision tree populated with a plurality of likely entropy returns in order for comparison; and
incorporating the occurrences of entropy returns into a Bayesian model including a predetermined number of bad data sets and good data sets to provide a probability result.

10. A computer readable medium on which is stored a computer program for executing the following instructions:
parsing a suspect file to extract a byte code sequence;
modeling the extracted byte code sequence using at least one entropy modeling test, each modeling test providing an entropy result based on the modeling of the extracted byte code sequence;
comparing each entropy result to a table of entropy results to determine a probability value; and
summing the probability values to determine a likelihood the byte code sequence is malicious.

11. The medium of claim 10, wherein the byte code sequence is deemed malicious when the sum of the probability values exceeds a predetermined threshold value.

12. A malware resistant computer system, comprising:
a processing unit;
a memory unit; and
a computer file system,
wherein the processing unit is configured to execute operations to detect malware, the operations comprising:
parsing a suspect file to extract a byte code sequence;
modeling the extracted byte code sequence using at least one entropy modeling test, each modeling test providing an entropy result based on the modeling of the extracted byte code sequence;
comparing each entropy result to a table of entropy results to determine a probability value; and
summing the probability values to determine a likelihood the byte code sequence is malicious.

13. The method of claim 12, wherein the byte code sequence is deemed malicious when the sum of the probability values exceeds a predetermined threshold value.

14. The method of claim 12, further comprising disposing of the suspect file when the byte code sequence is determined to be malicious, disposing of the malicious file including at least one of quarantining the malicious file and deleting the malicious file.

15. A method of detecting malware, the method comprising the operations:
receiving a suspect file;
preparing the received suspect file;
performing a heuristic analysis on the prepared suspect file using a plurality of entropy modeling tests to provide a plurality of entropy results;
performing a rule processing analysis on the plurality of entropy results to provide a plurality of deterministic results; and
declaring the suspect file is malware when a weighted sum of the deterministic results exceeds a predetermined threshold value.

16. The method of claim 15, wherein preparing the received suspect file includes at least one of:
generating at least one file hook for the received suspect file;
creating at least one process hook for the received suspect file; and
analyzing incoming network traffic related to the received suspect file.

17. The method of claim 15, wherein the entropy modeling test is selected from a group consisting of a 0-order Markov test, a 0-order arithmetic test, a 1-order uni-gram test, and a 2-order bi-gram test.

18. The method of claim 15, further comprising:
generating an anti-forgery rule database including a plurality of rules comprising at least one of a user added rule provided by a user and a system added rule provided automatically by a forgery detection system.

19. The method of claim 15, further comprising disposing of the suspect file when the suspect file is determined to be malware.

20. The method of claim 19, wherein disposing of the malicious file includes at least one of quarantining the malicious file and deleting the malicious file.
